(19) United States
(12) Patent Application Publication
(10) Pub. No.: US 2025/0311395 A1
(43) Pub. Date: Oct. 2, 2025

(54) VERTICAL DIODES WITH FRONT AND BACK CONTACTS

(71) Applicant: Intel Corporation, Santa Clara, CA (US)

(72) Inventors: Abhishek A. Sharma, Portland, OR (US); Tahir Ghani, Portland, OR (US); Sagar Suthram, Portland, OR (US); Anand S. Murthy, Portland, OR (US); Wilfred Gomes, Portland, OR (US)

(73) Assignee: Intel Corporation, Santa Clara, CA (US)

(21) Appl. No.: 18/619,694

(22) Filed: Mar. 28, 2024

(51) Int. Cl. H01L 27/06; H01L 29/06

(52) U.S. Cl. CPC H10D 84/811; H10D 62/124

(57) ABSTRACT

Vertical diodes are included in a device plane of an integrated circuit device, e.g., a diode array is in the same plane as a transistor array. The vertical diodes are semiconductor diodes, or p-n diodes, that have two contacts stacked vertically over and under the diode. The vertical diodes may be formed around a fin, e.g., with a front-side contact over the fin and a back-side contact under the fin. One or more diodes may be electrically coupled to a transistor to provide electrostatic discharge protection.

### BACKGROUND

Electrostatic discharge (ESD) events can be damaging for electronic devices. Transistors and other semiconductor-based devices typically have a voltage tolerance; if the voltage tolerance for a particular device is exceeded, the device may be damaged or degraded. ESD events can create voltage spikes or excess charges that can damage these electronic devices. Thus, when designing integrated circuit (IC) devices or packages, it is useful to have a way to protect against ESD events.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates a cross-section of a vertical diode that may be used for mitigating ESD events, according to some embodiments of the present disclosure.

FIGS. 2A and 2B are two cross-sections illustrating a first example diode formed around semiconductor fins, according to some embodiments of the present disclosure.

FIGS. 3A and 3B are two cross-sections illustrating a second example diode formed around semiconductor fins with different isolation structures and backside contacts, according to some embodiments of the present disclosure.

FIGS. 4A and 4B are two cross-sections illustrating a third example diode formed around semiconductor fins with wider backside contacts, according to some embodiments of the present disclosure.

FIGS. 5A and 5B are two cross-sections illustrating a fourth example diode formed around isolated semiconductor fins, according to some embodiments of the present disclosure.

FIGS. 6A and 6B are two cross-sections illustrating a diode formed around semiconductor nanoribbons, and FIG. 6C is an alternate embodiment of a diode formed around semiconductor ribbons, according to some embodiments of the present disclosure.

FIGS. 7A-7C are three cross-sections illustrating a vertical diode and transistor formed in a device plane, according to some embodiments of the present disclosure.

FIGS. 8A and 8B are top views of a wafer and dies that include one or more vertical ESD diodes in accordance with any of the embodiments disclosed herein.

FIG. 9 is a cross-sectional side view of an IC device that may include one or more vertical ESD diodes in accordance with any of the embodiments disclosed herein.

FIG. 10 is a cross-sectional side view of an IC device assembly that may include one or more vertical ESD diodes in accordance with any of the embodiments disclosed herein.

FIG. 11 is a block diagram of an example computing device that may include one or more vertical ESD diodes in accordance with any of the embodiments disclosed herein.

FIG. 12 is a block diagram of an example processing device that includes an IC device with one or more vertical ESD diodes in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

A diode is a two-terminal device that conducts current in one direction, referred to as the forward direction, while generally blocking current in the opposite direction, referred to as the reverse direction. In the forward direction, current enters through one terminal, which is called the anode, and leaves through the other terminal, which is called the cathode. When at least a minimum voltage, referred to as a forward voltage, is applied to the anode, this turns on the diode and current flows across the diode in the forward direction, from the anode to the cathode. Different types of materials may be used to form a diode. A semiconductor diode includes a p-n junction, which is an interface between two types of semiconductor materials, p-type and n-type. Semiconductor diodes may include silicon, germanium, or other types of semiconductor materials.

ESD diodes can be used to manage ESD events in an IC device. ESD diodes have previously been incorporated over the wafers used for constructing transistor devices. For example, a portion of a semiconductor surface (e.g., a wafer or die) is used to form ESD diodes, which can be connected to transistors formed over another portion of the semiconductor surface. Thus, the ESD diodes consume a portion of the surface area, and this portion cannot be used for transistors. In some cases, transistors are formed over one side of a wafer (e.g., the front side of a semiconductor wafer), and ESD diodes are formed on the opposite side (e.g., the back side of the semiconductor wafer). However, this requires connections between the front and back side of the wafer, and may result in a thicker device than desired.

As disclosed herein, diodes may be arranged vertically across a device plane or transistor plane of an IC device. The diodes are arranged with one terminal over the device plane, and the other terminal under the device plane. The front terminal, over the device plane, is formed over the wafer on which the transistors are formed. The back terminal, under the device plane, is formed on the back side or under side of the wafer over which the transistors are formed. The wafer is thinned prior to forming the back-side connections. In some cases, the transistors may also include contacts over and under the device plane; for example, in a back-gated transistor, the gate contact may be on the back side. Alternatively, one or both of the source/drain contacts may be backside contacts. In other cases, all of the transistor contacts may be formed on the same side (i.e., front side or the back side).

An IC device includes various circuit elements, such as transistors and, in this case, diodes, that are coupled together by metal interconnects. The circuit elements and metal interconnects may be formed in different layers. In particular, one or more layers of an IC device in which transistors, diodes, and/or other IC components are implemented may be referred to as a “transistor layer” or “device layer”. Layers with conductive interconnects for providing electrical connectivity (e.g., in terms of signals and power) to the transistors and/or other devices of the transistor layer of the IC device may be referred to as a “metal layer,” “metallization layer,” or “interconnect layer”. For example, the device layer may be a front-end-of-line (FEOL) layer, while the metal layers may be back-end-of-line (BEOL) layers formed over the FEOL layer. A set of metallization layers are referred to as a metallization stack. In some embodiments disclosed herein, a first metallization stack is formed over a front side of the device layer, and a second metallization stack is formed over the back side of the IC device, i.e., on an opposite side of the device layer from the first metallization stack. The second metallization stack may be coupled to back-side contacts of the diodes and transistors.

In general, forming device contacts on the back side of the device can provide certain advantages. For example, including both front and back side contacts enables routing on both sides of the device, which can offer different options for forming connections between transistors and/or diodes. Furthermore, including contacts and routing on both sides of the device can also help increase density of transistors. In particular, using vertical diodes with front- and back-side contacts rather than horizontal diodes with two contacts in the same side can lead to increased density of diodes in the IC device; this may enable increasing a number of diodes that may be included and/or reducing the amount of surface area (e.g., wafer area or die area) consumed by diodes.

To fabricate backside contacts, at least some portions of the devices and routing are typically formed over a front side of the wafer, followed by a metallization stack, as described above. The assembly is then flipped, and the wafer is thinned, e.g., by a grinding process, to reveal the back side of the devices. Then, the backside contacts are formed on the back sides of the transistor, followed by one or more back-side metal layers. Removing most or all of the thickness of the wafer can result in a relatively thin IC package. Thus, the vertical diodes with front-side and back-side contacts, described herein, consume a relatively small amount of surface area (e.g., compared to horizontal diodes), and can be fabricated in an IC device with a low height (as a result of thinning the wafer).

As noted above, the vertical diodes described herein are formed within a device plane, with one contact over the device plane and one contact under the device plane. In certain embodiments, a semiconductor diode is formed in the same layer as a set of transistors. The diode includes two semiconductor regions of different semiconductor types, forming a p-n junction. A pair of terminals, e.g., metal contacts, are each coupled to one of the semiconductor regions, forming an anode at one end and a cathode at the other end. The anode is coupled to one or more transistor devices, and the cathode is coupled to a ground. In an ESD event, the voltage at the anode may exceed the forward voltage, turning on the diode and sending the current to the ground, thus protecting the transistor devices. In normal operations (e.g., when there is no ESD event), the diode is turned off.

Certain embodiments of the diodes described herein include fin-shaped semiconductors regions forming the bulk semiconductor material. Semiconductor fins are often used in fin-shaped transistor devices, referred to as FinFET. FinFETs are transistors having a non-planar architecture where a fin, formed of one or more semiconductor materials, extends away from a base (where the term “base” refers to any suitable support structure on which a transistor may be built, e.g., a substrate). A portion of the fin that is closest to the base may be enclosed by an insulator material. Such an insulator material, typically an oxide, is commonly referred to as a “shallow trench isolation” (STI), and the portion of the fin enclosed by the STI is typically referred to as a “subfin portion” or simply a “subfin.” A gate stack that includes at least a layer of a gate electrode material and, optionally, a layer of a gate dielectric may be provided over the top and sides of the remaining upper portion of the fin (i.e., the portion above and not enclosed by the STI), thus wrapping around the upper-most portion of the fin. The portion of the fin over which the gate stack wraps around is typically referred to as a “channel portion” of the fin because this is where, during operation of the transistor, a conductive channel forms, and is a part of an active region of the fin. Two S/D regions are provided on the opposite sides of the gate stack, forming a source and a drain terminal of a transistor. FinFETs may be implemented as “tri-gate transistors,” where the name “tri-gate” originates from the fact that, in use, such transistors may form conducting channels on three “sides” of the fin. FinFETs potentially improve performance relative to single-gate transistors and double-gate transistors.

Other embodiments of the diodes described herein include nanoribbon or nanowire-based semiconductors regions forming the bulk semiconductor material. In general, in a nanowire-based transistor or nanoribbon-based transistor (referred to generally as a nanoribbon transistor), a gate stack that may include a stack of one or more gate electrode metals and, optionally, a stack of one or more gate dielectrics may be provided around one or more elongated semiconductor structures called “nanoribbons”, forming a gate on all sides of the nanoribbon or nanoribbons. A portion of a nanoribbon around which the gate stack wraps around is referred to as a “channel” or a “channel portion.” A semiconductor material of which the channel portion of the nanoribbon is formed is commonly referred to as a “channel material.” A source region and a drain region are provided on the opposite ends of the nanoribbon, on either side of the gate stack, forming, respectively, a source and a drain of such a transistor.

The vertical ESD diodes described herein may be implemented in combination with one or more components associated with an IC. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value, unless specified otherwise. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g., logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

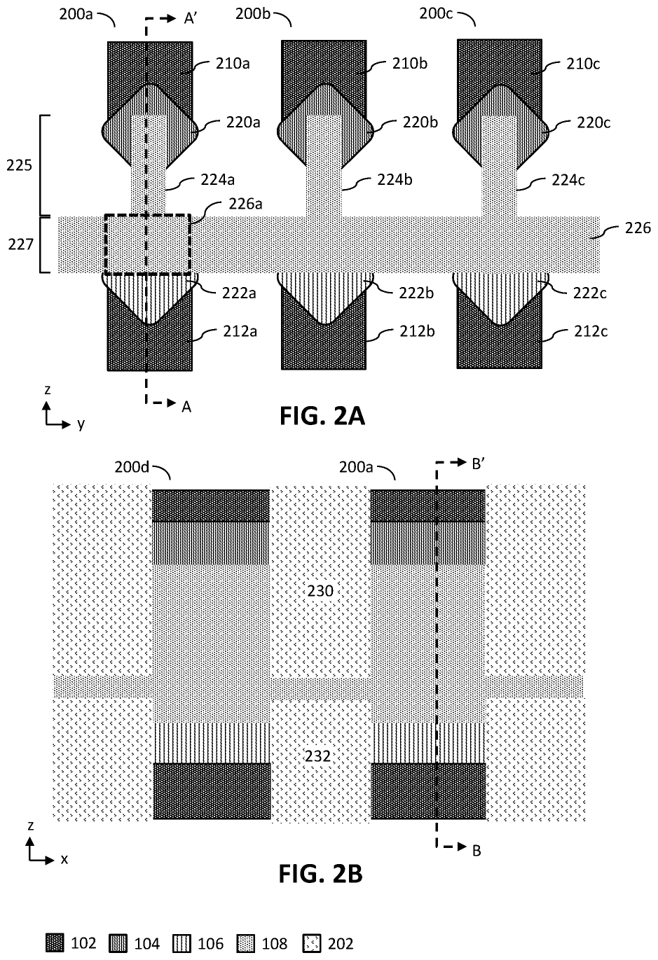

For convenience, if a collection of drawings designated with different letters are present, e.g., FIGS. 2A-2B, such a collection may be referred to herein without the letters, e.g., as “FIG. 2.”

### Example ESD Diode

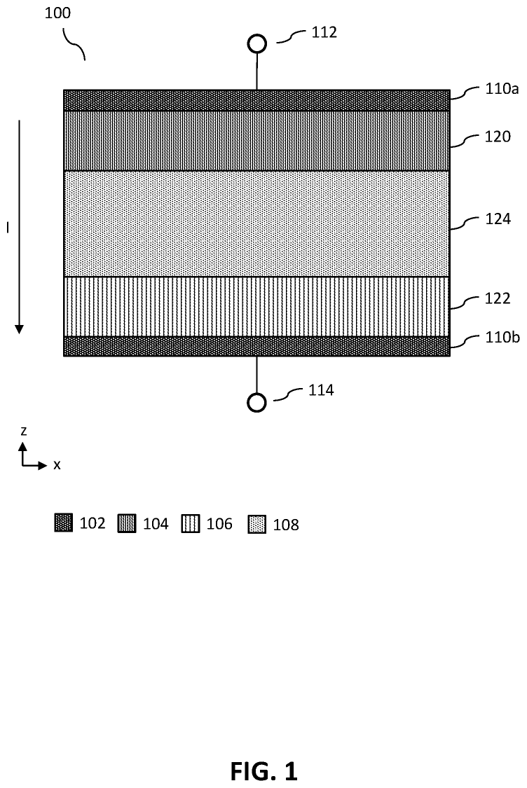

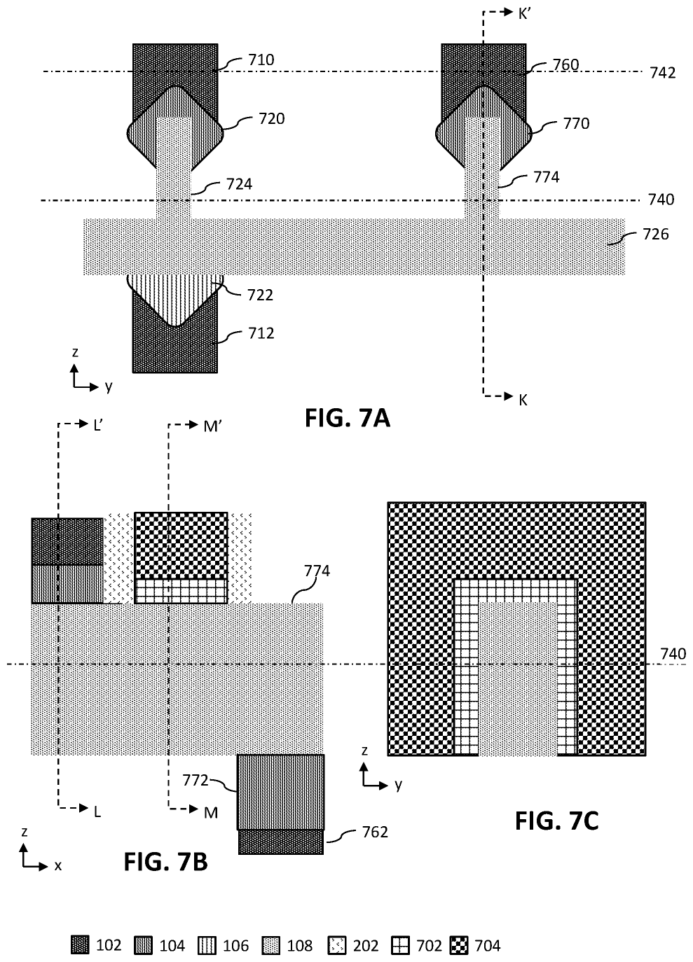

FIG. 1 illustrates a cross-section of a vertical diode that may be used for mitigating ESD events, according to some embodiments of the present disclosure. The diode 100 may be included in an IC device, as shown in FIGS. 2-7, e.g., along a device plane with transistor devices, as shown in FIG. 7. A number of elements referred to in the description of FIGS. 1-7 with reference numerals are illustrated in these figures with different patterns, with a legend showing the correspondence between the reference numerals and patterns being provided at the bottom of the drawing pages. For example, the legend in FIG. 1 illustrates that FIG. 1 uses different patterns to show a conductor 102, a first doped semiconductor material 104, a second doped semiconductor material 106, and a bulk semiconductor material 108.

The diode 100 includes two layers 110a and 110b of the conductor 102, a first doped region 120 of the first doped semiconductor material 104, a second doped region 122 of the second doped semiconductor material 106, and a bulk semiconductor region 124 of the bulk semiconductor material 108. The layers 110a and 110b are generally referred to as metal layers, and the layers 120-124 are generally referred to as semiconductor layers. Two terminals 112 and 114 are represented on the metal layers 110a and 110b; in this case, the terminal 112 is the anode, and the terminal 114 is the cathode. The forward direction, from the anode 112 to the cathode 114, is indicated by the arrow labelled I.

The conductor 102 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, the conductor 102 may include one or more electrically conductive alloys, oxides, or carbides of one or more metals.

One or more of the semiconductor materials 104, 106, and 108 may include a monocrystalline semiconductor, such as silicon (Si) or germanium (Ge). In some embodiments, one or more of the semiconductor materials may include a compound semiconductor with a first sub-lattice of at least one element from group III of the periodic table (e.g., Al, Ga, In), and a second sub-lattice of at least one element of group V of the periodic table (e.g., P, As, Sb).

For some embodiments, one or more of the semiconductor materials may include a III-V material having a high electron mobility, such as, but not limited to InGaAs, InP, InSb, and InAs. For some such embodiments, one or more of the semiconductor materials may be a ternary III—V alloy, such as InGaAs, GaAsSb, InAsP, or InPSb. For some InₓGa₁₋ₓAs embodiments, the In content (x) may be between 0.6 and 0.9, and may advantageously be at least 0.7 (e.g., In_{0.7}Ga_{0.3}As). For other embodiments, one or more of the semiconductor materials may be a group IV material having a high hole mobility, such as, but not limited to Ge or a Ge-rich SiGe alloy. For some example embodiments, one or more of the semiconductor materials may have a Ge content between 0.6 and 0.9, and may be at least 0.7.

In some embodiments, one or more of the semiconductor materials may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, one or more of the semiconductor materials may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus. Suitable dopants for one or more of the semiconductor materials 104, 106, and 108 may include gallium, indium, aluminum, fluorine, boron, phosphorus, arsenic, nitrogen, tantalum, tungsten, magnesium, etc.

The semiconductor materials 104, 106, and 108 of the first doped region 120, second doped region 122, and bulk semiconductor region 124, respectively, are selected to produce a p-n junction. The first doped region 120 and second doped region 122 have different charge carrier types. In conductor and semiconductor materials, a charge carrier is a particle or quasiparticle that can move within the material, carrying a conductive charge and resulting in a net motion of particles through the material. In some semiconductors, the main charge carriers are electrons, while in others, the main charge carriers are electron holes (i.e., electron vacancies), generally referred to as holes. A semiconductor material or semiconductor region with holes as the primary charge carrier is referred to as p-type, and a semiconductor material or semiconductor region with electrons as the primary charge carrier is referred to as n-type. Doping may be used to create a p-type or n-type material; for example, silicon can be doped such that it is either n-type or p-type. Having an opposite charge carrier one portion of the diode 100 (e.g., the first doped region 120) compared to another portion of the diode 100 (e.g., the second doped region 122) can create a p-n junction.

In general, the bulk semiconductor material 108 may have a relatively low level of a dopant, e.g., a lower dopant concentration than the first doped semiconductor material 104 and/or the second doped semiconductor material 106. The bulk semiconductor material 108 may have a same type of dopant as the first doped semiconductor material 104 or the second doped semiconductor material 106, but at a lower level. For example, the first doped semiconductor material 104 is a highly-doped n-type material, the bulk semiconductor material 108 is a lower-doped n-type material, and the second doped semiconductor material 106 is a p-type material. As another example, the first doped semiconductor material 104 is a highly-doped p-type material, the bulk semiconductor material 108 is a lower-doped p-type material, and the second doped semiconductor material 106 is an n-type material. While in these examples, the bulk semiconductor material 108 has the same dopant type as the first doped semiconductor material 104, in other examples, the bulk semiconductor material 108 has the same dopant type as the second doped semiconductor material 106.

The bulk semiconductor region 124 provides mechanical support to the diode structure, as well as electrical isolation between the first doped region 120 and second doped region 122. Additionally, the bulk semiconductor region 124 helps to prevent the depletion region, which forms at the junction of the p-type and n-type materials when the diode is biased, from extending across the diode 100 and causing unwanted leakage currents.

The vertical diode 100 may extend vertically through a device layer, where the metal layer 110a is a first contact (e.g., a front-side contact) on one side of the device layer, and the metal layer 110b is a second contact (e.g., a back-side contact) on the opposite side of the device layer. An array of multiple similar diodes may be formed across a device layer. FIGS. 2-7 provide different example configurations of arrays of the diode 100.

### Example Arrays of Vertical ESD Diodes

FIGS. 2A and 2B are two cross-sections illustrating a first set of example diodes 200 formed around semiconductor fins, according to some embodiments of the present disclosure. FIG. 2A illustrates cross-sections through three diodes 200a, 200b, and 200c. Each diode 200 is formed around a respective semiconductor fin 224a, 224b, or 224c, referred to jointly as semiconductor fins 224. Each diode 200 includes a first doped semiconductor region 220 (e.g., the first doped semiconductor regions 220a, 220b, and 220c of the diodes 200a, 200b, and 200c, respectively) and a second doped semiconductor region 222 (e.g., the second doped semiconductor regions 222a, 222b, and 222c of the diodes 200a, 200b, and 200c, respectively). The first doped semiconductor regions 220 correspond to the first doped region 120 of the diode 100, and the second doped semiconductor regions 222 correspond to the second doped region 122 of the diode 100. Each diode 200 further includes a first contact 210 (e.g., the first contacts 210a, 210b, and 210c of the diodes 200a, 200b, and 200c, respectively) and a second contact 212 (e.g., the second contacts 212a, 212b, and 212c of the diodes 200a, 200b, and 200c, respectively). The first contacts 210 correspond to the first metal layer 110 of the diode 100, and the second contacts 212 correspond to the second metal layer 110b of the diode 100.

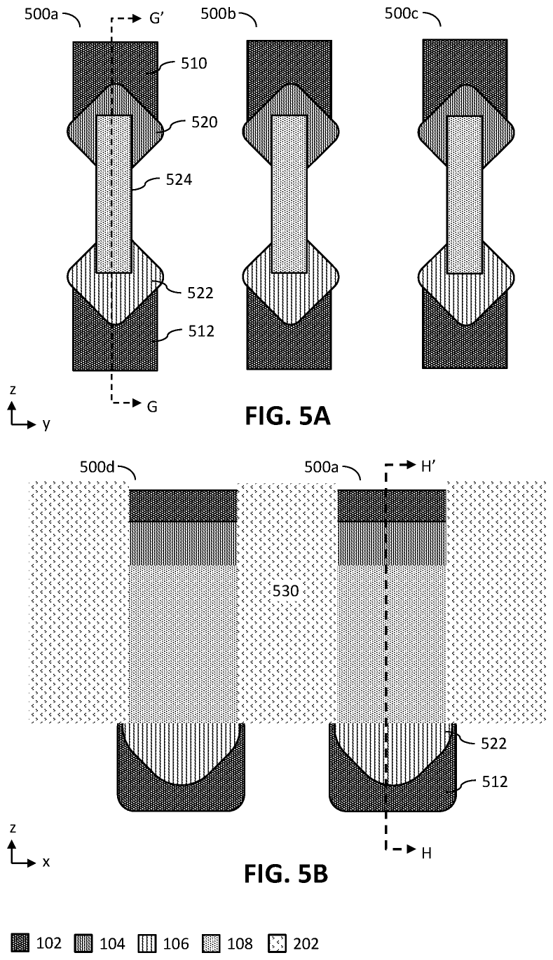

The semiconductor fins 224 are formed in or over a semiconductor substrate 226, e.g., a semiconductor wafer. The semiconductor wafer may have an initial thickness of, e.g., several hundred microns to over 1 millimeter. After frontside processing, a portion of the semiconductor wafer is thinned, either removing the semiconductor substrate 226 entirely (e.g., as in the example shown in FIG. 5), or reducing the thickness 227 of the semiconductor substrate 226 to a few nanometers or a few tens of nanometers, e.g., between 1 and 100 nanometers, between 1 and 40 nanometers, between 1 and 20 nanometers, between 1 and 10 nanometers, between 1 and 5 nanometers, less than 50 nanometers, less than 25 nanometers, less than 10 nanometers, less than 5 nanometers, or within some other range. While the semiconductor fins 224 are shown as having a rectangular cross-section in the y-z plane of the reference coordinate system shown, the semiconductor fins 224 may instead have a cross-section that is rounded or sloped at the “top” of the semiconductor fins 224, and the first doped semiconductor regions 220 may conform to this shape.

The semiconductor fins 224, as well as the first doped semiconductor regions 220 and first contacts 210, are formed over the semiconductor substrate 226 prior to thinning the semiconductor substrate 226 to the thickness 227. The semiconductor fins 224 may extend away from the semiconductor substrate 226 and may be substantially perpendicular to the semiconductor substrate 226. The semiconductor fins 224 may have a height 225, a dimension measured in the direction of the z-axis of the reference coordinate system, which may, in some embodiments, be between about 20 and 350 nanometers, including all values and ranges therein (e.g. between about 40 and 150 nanometers, between about 75 and 250 nanometers, or between about 150 and 300 nanometers). In some embodiments, the semiconductor fin 224 may have a minimum height of 20 nanometers, 25 nanometers, 30 nanometers, 40 nanometers, or 50 nanometers.

The semiconductor fins 224 and the semiconductor substrate 226, jointly, correspond to the bulk semiconductor region 124 of the diode 100. For example, for the diode 200a, the semiconductor fin 224a and the portion 226a of the semiconductor substrate 226 correspond to the bulk semiconductor region 124. An upper end of the semiconductor fin 224 forms a first end of the bulk semiconductor region of the diode 200, and the base of the semiconductor substrate 226 forms a second end of the bulk semiconductor region of the diode 200.

After thinning the semiconductor substrate 226, the second doped semiconductor regions 222 and second contacts 212 are formed on the back side of the assembly. In some embodiments, the frontside elements of the diodes 200 (i.e., the semiconductor fins 224, first doped semiconductor regions 220, and first contacts 210) are formed, followed by a metallization stack that includes conductive structures coupled to the first contacts 210. For example, the conductive structures may couple the first contacts 210 to one or more transistor devices, which may be formed in the same layer as the diodes 200. The assembly is then flipped, exposing the back side of the semiconductor substrate 226, which is thinned to the thickness 227. The second doped semiconductor regions 222 and second contacts 212 may generally be formed using a similar process to the first doped semiconductor regions 220 and first contacts 210.

In some embodiments, the first doped semiconductor regions 220 and/or the second doped semiconductor regions 222 may be formed by epitaxial growth. An epitaxial growth can result in a generally diamond-shaped structure, as shown in FIG. 2, due to the crystallographic orientation of the underlying semiconductor material (e.g., the semiconductor fins 224 and semiconductor substrate 226) and/or the growth process itself. Specifically, during an epitaxial deposition process, the growth tends to follow the crystal structure of the underlying structures, with a higher growth rate along certain crystallographic directions compared to others.

While not specifically shown in FIG. 2A, one or more dielectric materials may be present between the diodes 200, e.g., between the diodes 200a and 200b and between the diodes 200b and 200c. In some embodiments, a fin trim isolation (FTI) region may be used to isolate individual fins in the x-direction, as illustrated in FIG. 2B. When forming transistor arrays, FTI may be inserted along a gate line, i.e., between two source/drain regions of different transistors. When semiconductor fins, such as the semiconductor fins 224, are used to form diodes, the gate regions may be replaced with FTI regions, thus forming individual vertical diodes along portions of the fins that could be used to form source and drain regions.

More specifically, FIG. 2B illustrates a cross-section through the plane AA′ of FIG. 2A, where the plane AA′ extends through the diode 200a. FIG. 2B illustrates a perpendicular cross-section of the diode 200a, through the x-z plane; FIG. 2A is a cross-section through the plane BB′ of FIG. 2B. FIG. 2B includes an additional diode 200d, which is at a different position in the x-direction from the diode 200a. An array of the diodes 200 (e.g., the diodes 200a-200d) generally extends in the x-direction and y-direction of the coordinate system shown. A region of an IC device that extends in the x-direction and y-direction that includes diodes 200 and, in some cases, other semiconductor devices (e.g., transistors) may generally be referred to as a device area or device plane. An example device plane that includes a diode and a transistor is illustrated in FIG. 7.

The diodes 200a and 200d are separated by two FTI regions 230 and 232, where FTI region 230 is a frontside FTI region, and FTI region 232 is a backside FTI region. The FTI regions 230 and 232 are formed from an isolation material 202, which may generally include low-k or high-k dielectrics including, but not limited to, elements such as hafnium, silicon, oxygen, nitrogen, titanium, tantalum, lanthanum, aluminum, zirconium, barium, strontium, yttrium, lead, scandium, niobium, and zinc. Further examples of the isolation material 202 include, but are not limited to silicon nitride, silicon oxide, silicon dioxide, silicon carbide, silicon nitride doped with carbon, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate.

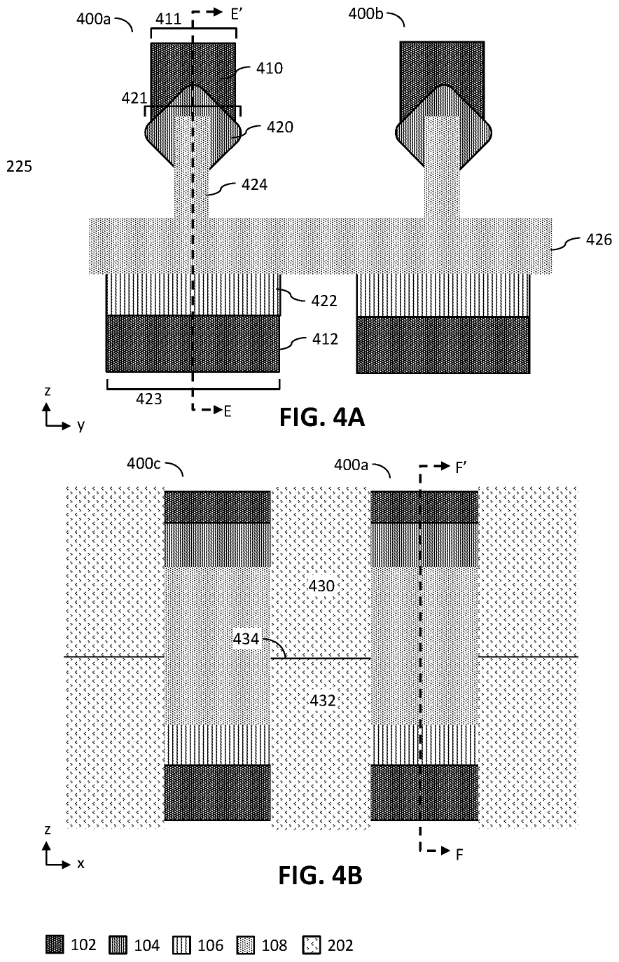

In this example, the frontside FTI regions (e.g., the FTI region 230) are formed after growth of the first doped semiconductor regions 220 and, in some cases, after the deposition of the first contacts 210. The frontside FTI regions extend partially through the semiconductor substrate 226. The backside FTI regions (e.g., the FTI region 232) are formed after growth of the second doped semiconductor regions 222 and, in some cases, after deposition of the second contacts 212. The backside FTI regions also extend partially through the semiconductor substrate 226, but do not join with the frontside FTI regions, e.g., a portion of the semiconductor substrate 226 remains between the FTI regions 230 and 232. In other embodiments, the frontside and backside FTI regions 230 and 232 meet at a seam, e.g., as shown in FIG. 4B.

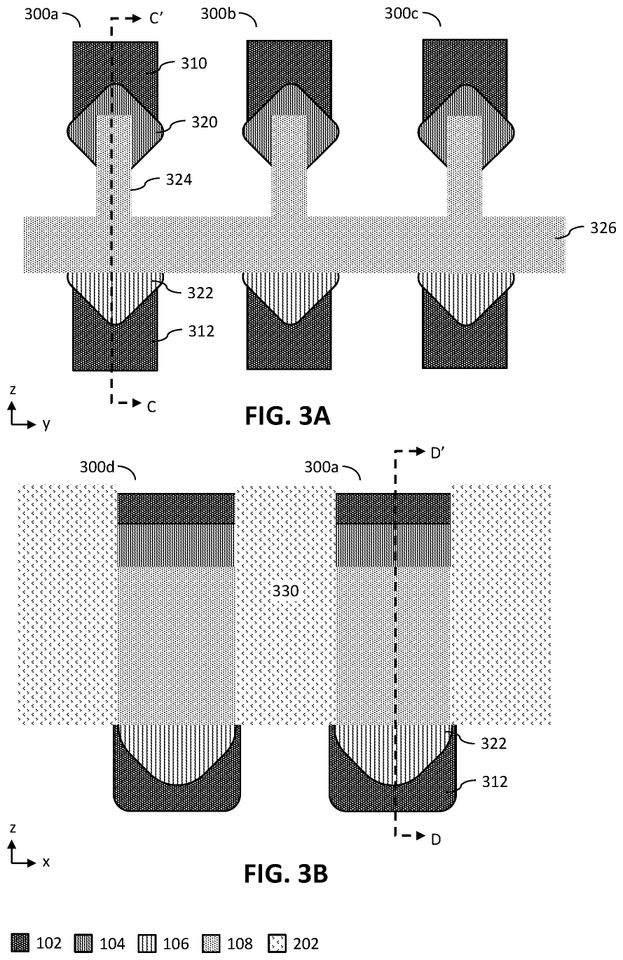

In another embodiment, the frontside FTI regions extend fully through the semiconductor substrate. An example of this is shown in FIGS. 3A and 3B. FIGS. 3A and 3B are two cross-sections illustrating a second set of example diodes 300 formed around semiconductor fins with different isolation structures and backside contacts, according to some embodiments of the present disclosure. FIG. 3B is a cross-section through the plane CC′ in FIG. 3A, and FIG. 3A is a cross-section through the plane DD′ in FIG. 3B.

FIG. 3A illustrates cross-sections through three diodes 300a, 300b, and 300c. Each diode 300 is formed around a respective semiconductor fin, e.g., the semiconductor fin 324 of diode 300a, which is similar to the semiconductor fins 224 of FIG. 2. Each diode 300 includes a first doped semiconductor region (e.g., the first doped semiconductor region 320 of diode 300a) and a first contact (e.g., the first contact 310 of diode 300a), which are similar to the first doped semiconductor regions 220 and first contacts 210 of FIG. 2.

The semiconductor fins (e.g., the semiconductor fin 324) are over and extend away from a semiconductor substrate 326. The semiconductor substrate 326 is similar to the semiconductor substrate 226, described above. However, rather than two opposing FTI regions 230 and 232 cutting partially through the semiconductor substrate 226, as shown in FIG. 2B, a single FTI region 330 extends fully through the portions of the semiconductor substrate 326, as shown in FIG. 3B.

The diodes 300 each further include a second doped semiconductor region (e.g., the second doped semiconductor region 322 of diode 300a) and a second contact (e.g., the second contact 312 of diode 300a). In the cross-section of FIG. 3A, the second doped semiconductor region and the second contacts are similar to the second doped semiconductor regions 222 and second contacts 212 of FIG. 2A. In the cross-section of FIG. 3B, however, the second doped semiconductor regions have a different shape from the second doped semiconductor regions 222 shown in FIG. 2B. In this example, the second doped semiconductor regions (e.g., the second doped semiconductor region 322) are deposited, e.g., using epitaxial growth, over the semiconductor material (e.g., the semiconductor fin 324) but not over the isolation material 202 of the FTI region 330. In this example, a second dielectric material (not shown in FIG. 3B) may extend between the second contacts of the adjacent diodes 300a and 300d, below the FTI region 330.

In the examples of FIGS. 2 and 3, the front and back side doped semiconductor regions (e.g., the regions 220 and 222, and the regions 320 and 322) have similar sizes and shapes, e.g., a maximum width of the first doped semiconductor region 220a in the y-direction is similar to or the same as a maximum width of the second doped semiconductor region 222a in the y-direction. In other examples, one of the doped semiconductor regions may be larger than the other. Making one of the doped semiconductor regions (e.g., the second doped semiconductor region 222) larger may increase the amount of ESD current that can pass through the diode.

FIGS. 4A and 4B are two cross-sections illustrating a third example set of diodes 400 formed around semiconductor fins with wider backside contacts, according to some embodiments of the present disclosure. FIG. 4B is a cross-section through the plane EE′ in FIG. 4A, and FIG. 4A is a cross-section through the plane EE′ in FIG. 4B.

FIG. 4A illustrates cross-sections through two diodes 400a and 400b. Each diode 400 is formed around a respective semiconductor fin, e.g., the semiconductor fin 424 of diode 400a, which is similar to the semiconductor fins 224 of FIG. 2. Each diode 400 includes a first doped semiconductor region (e.g., the first doped semiconductor region 420 of diode 400a) and a first contact (e.g., the first contact 410 of diode 400a), which are similar to the first doped semiconductor regions 220 and first contacts 210 of FIG. 2.

The semiconductor fins (e.g., the semiconductor fin 424) are over and extend away from a semiconductor substrate 426. The semiconductor substrate 426 is similar to the semiconductor substrate 426, described above. In this example, between adjacent diodes 400 in the x-direction (e.g., between the diodes 400c and 400a in FIG. 4B), opposing FTI regions 430 and 432 each cut partially through the semiconductor substrate 426, in a similar manner to the FTI regions 230 and 232 of FIG. 2B. However, unlike in FIG. 2B, the two FTI regions 430 and 432 together extend fully through the 426, meeting at a seam, e.g., the seam 434. In other embodiments, two FTI regions 430 and 432 may not meet (e.g., in the FTI arrangement shown in FIG. 2B), or a single FTI region may be used (e.g., as shown in FIG. 3B).

The diodes 400 each further include a second doped semiconductor region (e.g., the second doped semiconductor region 422 of diode 400a) and a second contact (e.g., the second contact 412 of diode 400a). In the cross-section of FIG. 4A, the second doped semiconductor region and the second contacts are wider than the second doped semiconductor regions 222 and second contacts 212 of FIG. 2A, and wider than the second doped semiconductor regions 322 and second contacts 312 of FIG. 3A. Furthermore, the second contact 412 is wider in the y-direction than the first contact 410, and the second doped semiconductor region 422 is wider in the y-direction than the first doped semiconductor region 420.

FIG. 4A illustrates widths of different features in the x-direction, e.g., in a direction along the shortest dimension of the semiconductor fin 424. In FIG. 4A, the first contact 410 has a width 411, and the first doped semiconductor region 420 has a width 421. The width 421 is measured at the widest point of the 420. The second contact 412 and the second doped semiconductor region 422 have a width 423, which is greater than the widths 411 and 421.

FIG. 4B illustrates cross-sections of features in the y-direction, e.g., in a direction along the second-shortest dimension of the semiconductor fin 424, which is perpendicular to the shortest direction (i.e., the x-direction) and the longest direction (i.e., the z-direction, or the height). In FIG. 4B, the first contact 410, first doped semiconductor region 420, second contact 412, and second doped semiconductor region 422 each have a same width in the x-direction. In other embodiments, the second contact 412 and second doped semiconductor region 422 may be wider than the first contact 410 and/or the first doped semiconductor region 420 in the y-direction.

In the examples shown in FIGS. 2-4, a portion of the semiconductor substrate 226, 326, or 426 remains after thinning, extending under the semiconductor fins 224, 324, or 424, as shown in FIGS. 2A, 3A, and 4A. In other embodiments, the full height of the semiconductor substrate is removed (e.g., by grinding), so that the bulk semiconductor region 124 is formed by the semiconductor fins, without a portion of the semiconductor substrate. Thus, the semiconductor fins are isolated from one another, without a semiconductor material extending between different fins, as shown in FIGS. 2A, 3A, and 4A.

FIGS. 5A and 5B are two cross-sections illustrating a fourth example diode formed around isolated semiconductor fins, according to some embodiments of the present disclosure. FIG. 5B is a cross-section through the plane GG′ in FIG. 5A, and FIG. 5A is a cross-section through the plane HH′ in FIG. 5B.

FIG. 5A illustrates cross-sections through three diodes 500a, 500b, and 500c. Each diode 500 is formed around a respective semiconductor fin, e.g., the semiconductor fin 524 of diode 500a, which is similar to the semiconductor fins 224 of FIG. 2. Each diode 500 includes a first doped semiconductor region (e.g., the first doped semiconductor region 520 of diode 500a) and a first contact (e.g., the first contact 510 of diode 500a), which are similar to the first doped semiconductor regions 220 and first contacts 210 of FIG. 2.

Unlike the embodiments of FIGS. 2-4, the semiconductor fins (e.g., the semiconductor fin 524) are not over a semiconductor substrate. The semiconductor fins may have been formed over a semiconductor substrate, and after fabrication of the first doped semiconductor regions, first contacts, and front-side metallization stack (among other structures), the assembly was flipped, and the full semiconductor substrate removed, thus exposing the back side of the semiconductor fins. The semiconductor substrate 326 is similar to the semiconductor substrate 226, described above.

The diodes 500 each further include a second doped semiconductor region (e.g., the second doped semiconductor region 522 of diode 500a) and a second contact (e.g., the second contact 512 of diode 500a). The second doped semiconductor regions (e.g., 522) and second contacts (e.g., 512) may generally be formed using a similar process to the first doped semiconductor regions and first contacts, e.g., as described above with respect to the first doped semiconductor regions 220 and first contacts 210 of FIG. 2. In this example, because the first and second doped semiconductor regions are formed on either end of the semiconductor fin, the first and second doped semiconductor regions (e.g., the regions 520 and 522) have generally symmetric shapes. In other embodiments, the first and second doped semiconductor regions (e.g., the regions 520 and 522) may be asymmetrical, e.g., due to different epitaxial growth patterns or crystal structures of the first doped semiconductor material 104 and second doped semiconductor material 106.

The cross-section of FIG. 5B is similar to the cross-section in FIG. 3B, with a single FTI region 530 extending along the height of the semiconductor fins of the diodes 500d and 500a. In other embodiments, the arrangement of the FTI and the shapes of the second doped semiconductor regions and second contacts may have a cross-section similar to that shown in FIG. 2B or FIG. 4B.

FIGS. 2-5 illustrated examples with fin-shaped bulk semiconductor regions. Diodes with fin-shaped semiconductor regions may be fabricated in a device layer that includes FinFETs, e.g., the FinFET shown in FIGS. 7A-7C. If a different transistor architecture is used in the IC device, the bulk semiconductor region of the vertical diode may have different shape. In other words, the bulk semiconductor of the vertical diode may have a shape corresponding to the transistor architecture of the IC device. For example, if an IC device includes nanowire or nanoribbon transistors, a vertical diode may include nanoribbons or nanowires in the bulk semiconductor region.

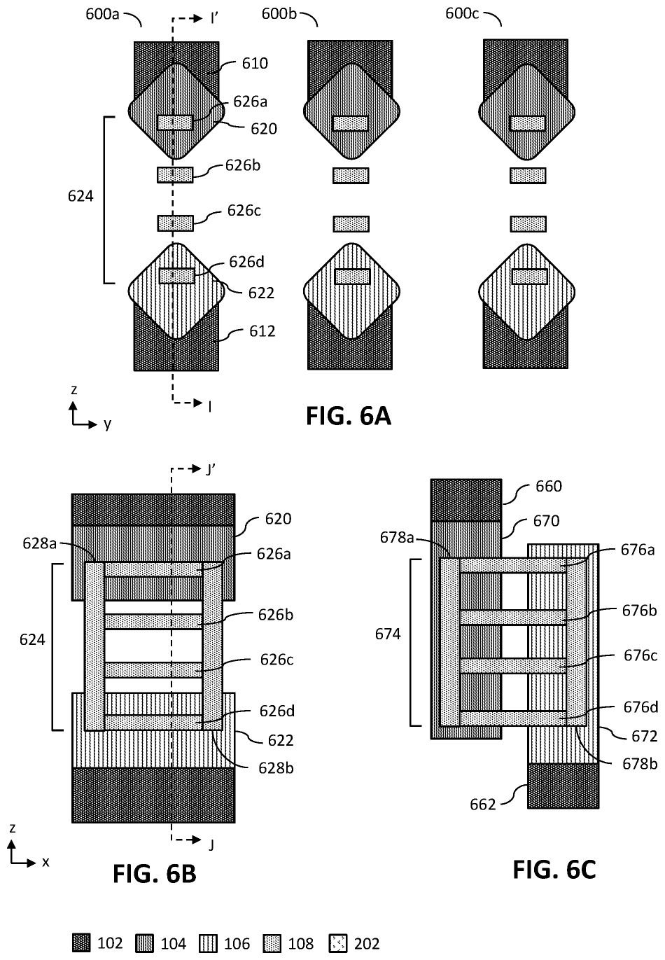

FIGS. 6A and 6B are two cross-sections illustrating a diode formed around semiconductor nanoribbons, according to some embodiments of the present disclosure. FIG. 6B is a cross-section through the plane II′ in FIG. 6A, and FIG. 6A is a cross-section through the plane JJ′ in FIG. 6B.

FIG. 6A illustrates cross-sections through three diodes 600a, 600b, and 600c. Each diode 600 is formed around a respective stack of nanoribbons, e.g., the stack 624 of nanoribbons of the diode 600a. The stack of nanoribbons corresponds to the bulk semiconductor region 124 of FIG. 1, e.g., the stack of nanoribbons replaces the semiconductor fin 524 of FIG. 5. In this example, each stack of nanoribbons includes a stack of four nanoribbons, e.g., the stack 624 of nanoribbons includes the nanoribbons 626a, 626b, 626c, and 626d.

The individual nanoribbons are shorted together so that current can flow in the vertical direction (e.g., the z-direction in the coordinate system of FIG. 6). For example, as shown in FIG. 6B, two semiconductor structures 628a and 628b are formed along the ends of the nanoribbons 626a, 626b, 626c, and 626d, thus forming a single semiconductor body. The semiconductor structures 628 extend vertically (in the z-direction) and may also extend into the y-direction, e.g., encasing the ends of the nanoribbons 626. While the semiconductor structures 628 are illustrated as including the same bulk semiconductor material 108 as the nanoribbons 626, in other embodiments, the semiconductor structures 628 may include a different semiconductor material. The semiconductor structures 628 may be formed by epitaxial deposition or another fabrication method. The semiconductor structures 628 may have a different shape or arrangement, e.g., the semiconductor structures 628 may extend partially or fully between adjacent nanoribbons 626, and may not have the rectangular shape illustrated in FIG. 6B.

The other structures of the diodes 600 may be similar to the diodes 500. For example, each diode 600 includes a first doped semiconductor region (e.g., the first doped semiconductor region 620 of diode 600a) and a first contact (e.g., the first contact 610 of diode 600a), which are similar to the first doped semiconductor regions 520 and first contacts 510 of FIG. 5. The diodes 600 each further include a second doped semiconductor region (e.g., the second doped semiconductor region 622 of diode 600a) and a second contact (e.g., the second contact 612 of diode 600a), which are similar to the second doped semiconductor regions 522 and second contacts 512 of FIG. 5. As shown in FIG. 6B, the first doped semiconductor region 620 is coupled to the upper nanoribbon 626a and the upper ends of the semiconductor structures 628, while the second doped semiconductor region 622 is coupled to the lower nanoribbon 626d and the lower ends of the semiconductor structures 628. Adjacent diodes 600 may be isolated by FTI, e.g., using any of the FTI arrangements illustrated in FIGS. 2-5.

FIG. 6C is an alternate cross-section of a diode formed around semiconductor ribbons. FIG. 6C is a cross-section in the x-z plane, e.g., a different embodiment of the view shown in FIG. 6B. In FIG. 6C, a diode is formed around a stack 674 of nanoribbons, which include the nanoribbons 676a, 676b, 676c, and 676d. The stack 674 is similar to the stack 624 of nanoribbons 626, described above. Like in FIG. 6B, the nanoribbons 676 are shorted together by two semiconductor structures 678a and 678b that are formed along the ends of the nanoribbons 676, thus forming a single semiconductor body. The semiconductor structures 678 extend vertically (in the z-direction) and may also extend into the y-direction, e.g., encasing the ends of the nanoribbons 676. The semiconductor structures 678 may be formed by epitaxial deposition or another fabrication method, as described above.

The diode includes a first doped semiconductor region 670 and a first contact 660, which are similar to the first doped semiconductor regions 620 and first contacts 610 of FIG. 5. The diodes each further include a second doped semiconductor region 672 and a second contact 662. In some embodiments, the doped semiconductor regions 670 and 672 serve as the semiconductor structures 678, and separate semiconductor structures 678 are not included. In this example, the first doped semiconductor region 670 extends down the stack 674 of nanoribbons 676 on the left side, while the second doped semiconductor region 672 extends up the stack 674 of nanoribbons 676 on the right side. The contacts 660 and 662 are offset relative to each other, rather than stacked directly over each other. In this case, current may primarily flow in a left-to-right direction.

### Example Vertical ESD Diode and Transistor Device

As described above, the vertical diodes, e.g., any of the diodes illustrated in FIGS. 2-6, may be included in a device plane or transistor plane of an IC device, with one terminal over the plane, and the other terminal under the plane. One or more other types of semiconductor devices, e.g., one or more transistors, can also be formed within the device plane. FIGS. 7A-7C are three cross-sections illustrating a vertical diode and transistor formed in a device plane, according to some embodiments of the present disclosure.

FIG. 7A illustrates a diode 700, which is similar to the diode 200. In other embodiments, the diode 700 may be any one of the diodes 300, 400, 500, or 600 of FIGS. 3-6. The diode 700 may have a cross-section through the x-z plane similar to the cross-sections illustrated in FIG. 2B or 3B, for example.

FIG. 7A further includes a cross-section through a transistor device 750. The transistor device 750 is a FinFET that includes a semiconductor fin 774, which is similar to the semiconductor fin 724. The semiconductor fin 774 may be longer than the semiconductor fin 724 in the x-direction. The semiconductor fin 774 extends upwards from a semiconductor substrate 726, which is similar to the semiconductor substrate 226. The semiconductor substrate 726 may form a subfin for semiconductor fin 774 of the transistor 750.

The transistor device 750 includes a first source/drain (S/D) region 770, which is similar to the first doped semiconductor region 720 of the diode 700, and a first S/D contact 760, which is similar to the first contact 710 of the diode 700. For example, the first S/D region 770 and first S/D contact 760 may be fabricated in a same process as the first doped semiconductor region 720 and first contact 710 of the diode 700.

A device plane 740 extends through the semiconductor devices 700 and 750. The device plane 740 extends in the x- and y-directions in the coordinate system shown. In this illustration, the device plane 740 extends through the semiconductor fin 774 of the transistor device 750 and the semiconductor fin 724 of the diode 700. A contact plane 742 is over the device plane 740; the contact plane 742 extends through the first contact 710 of the diode 700 and the first S/D contact 760 of the transistor 750. In this example, the first doped semiconductor region 720 and first S/D region 770 are also over the device plane 740, but are below the contact plane 742. The second doped semiconductor region 722 and second contact 712 of the diode 700 are below the device plane 740, so that the first doped semiconductor region 720 and first contact 710 are on an opposite side of the device plane 740 from the second doped semiconductor region 722 and second contact 712.

FIG. 7B illustrates a cross-section of the transistor device 750 through the plane KK′. FIG. 7A is a cross-section through the plane LL′ in FIG. 7B, and FIG. 7C is a cross-section through the plane MM′ in FIG. 7B. FIGS. 7B and 7C illustrate the gate stack of the transistor 750. The gate stack includes a gate dielectric 702 that wraps around a central portion of the semiconductor fin 774, and a gate electrode 704 that wraps around the gate dielectric 702.

The gate electrode 704 may include at least one P-type work function metal or N-type work function metal. For a PMOS transistor, metals that may be used for the gate electrode 704 may include, but are not limited to, ruthenium, palladium, platinum, cobalt, nickel, and conductive metal oxides (e.g., ruthenium oxide). For an NMOS transistor, metals that may be used for the gate electrode 704 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 704 may include a stack of two or more metal layers, where one or more metal layers are WF metal layers and at least one metal layer is a fill metal layer.

In various embodiments, the gate dielectric 702 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric 702 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric 702 during manufacture of the transistor 750 to improve the quality of the gate dielectric 702. In some embodiments, the gate dielectric 702 may have a thickness between about 0.5 nanometers and 3 nanometers, including all values and ranges therein, e.g., between about 1 and 3 nanometers, or between about 1 and 2 nanometers.

In some embodiments, the gate stack (i.e., the gate dielectric 702 and gate electrode 704) may be surrounded by a gate spacer, not shown in FIG. 7. Such a gate spacer would be configured to provide separation between the gate electrode 704 and the source/drain contacts of the transistor 750 and could be made of a low-k dielectric material, some examples of which have been provided above. A gate spacer may include pores or air gaps to further reduce its dielectric constant.

FIG. 7B further illustrates a second S/D region 772 and a second S/D contact 762. Here, the first S/D region 770, first S/D contact 760, and gate stack 702 and 704 are formed over the front side of the transistor 750, e.g., over the device plane 740, while the second S/D region 772 and second contact 762 are formed on the back side of the transistor 750, e.g., under the device plane 740. The second S/D region 772 and second S/D contact 762 may be formed in a same process as the second doped semiconductor region 722 and second contact 712 of the diode 700. In different embodiments, different ones of the S/D regions/contacts and/or gate stack may be formed over or under the device plane 740.

Notably, while the first contact 710, first doped semiconductor region 720, second doped semiconductor region 722, and second contact 712 are all aligned in the x- and y-directions, forming a vertical device where current travels vertically (e.g., in the z-direction) when the diode 700 is turned on, in the transistor 750, the first S/D contact 760 and first S/D region 770 are offset from the second S/D region 772 and second S/D contact 762 in the x-direction, so that when the transistor 750 is turned on, current travels horizontally in the x-direction through the transistor 750.

Furthermore, the fin length of the transistor 750 (e.g., a dimension of the semiconductor fin 774 in the x-direction, e.g., the horizontal dimension of the semiconductor fin 774 in FIG. 7B) may be longer than the fin length of the diode 700 (e.g., a dimension of the semiconductor fin 724 in the x-direction, e.g., the horizontal dimension of the semiconductor fins 224 in FIG. 2B). This is because the semiconductor fin 774 of the transistor 750 extends under the gate stack, e.g., including the length of two S/D regions and the gate, whereas the semiconductor fin 724 of the diode 700 is cut by the FTI region (which, in a transistor device, is positioned where the gate stack is), e.g., the FTI region 230, or any of the other FTI regions shown in FIGS. 3-6.

In some embodiments, the first contact 710 of the diode 700 is coupled to one of the terminals of the transistor 750, e.g., the first S/D contact 760 or gate electrode 704, while the second contact 712 is coupled to an electrical ground. The first contact 710 of the diode 700 may be coupled to the transistor 750 by conductive structures in one or more metal layers in the front-side metallization stack. If an ESD event occurs, the diode 700 turns on, and the high voltage is routed to the ground, rather than through the transistor 750. In other embodiments, the direction of the diode 700 is reversed, with the first contact 710 coupled to an electrical ground, and the second contact 712 coupled to one of the terminals of the transistor 750, e.g., the second S/D contact 762.

### Example Devices

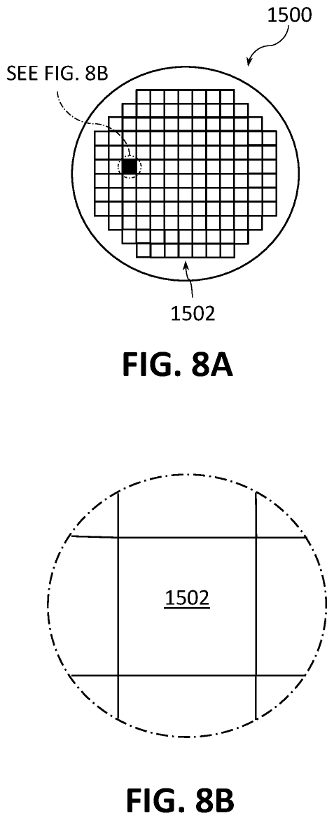

The circuit devices with one or more vertical ESD diodes disclosed herein may be included in any suitable electronic device. FIGS. 8-11 illustrate various examples of apparatuses that may include the one or more transistors disclosed herein, which may have been fabricated using the processes disclosed herein.

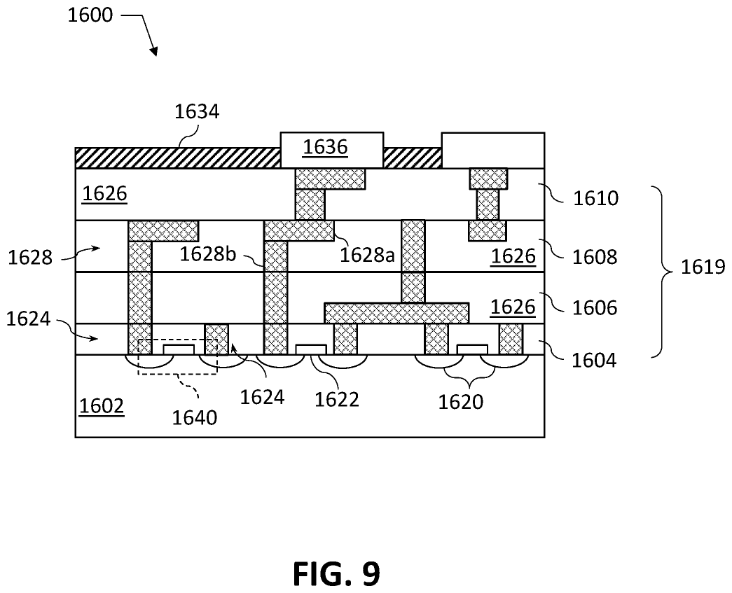

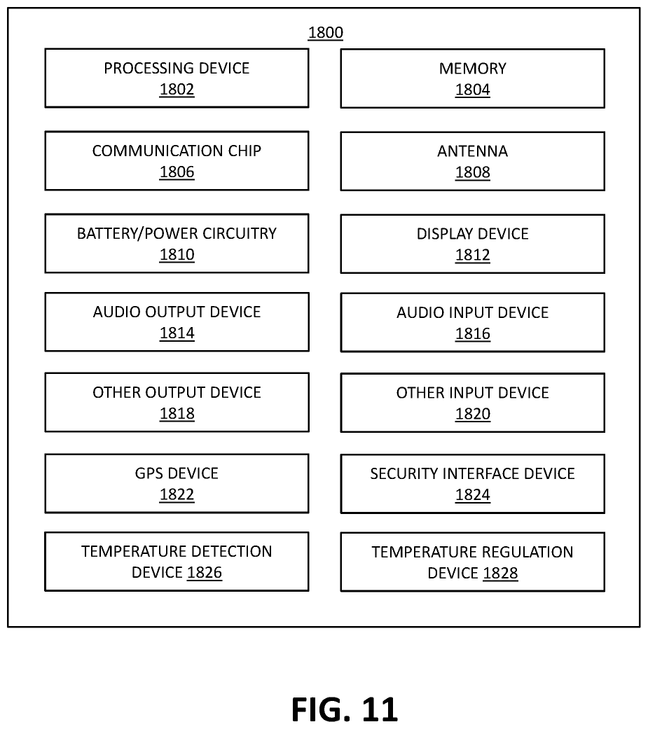

FIGS. 8A and 8B are top views of a wafer and dies that include one or more IC structures including one or more vertical ESD diodes in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 3-10, or any further embodiments of the IC structures described herein). After the fabrication of the semiconductor product is complete (e.g., after manufacture of one or more IC structures with one or more of the transistors as described herein, included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more of the transistors as disclosed herein may take the form of the wafer 1500 (e.g., not singulated) or the form of the die 1502 (e.g., singulated). The die 1502 may include one or more transistors (e.g., one or more of the transistors 1640 of FIG. 9, discussed below) and/or supporting circuitry to route electrical signals to the transistors, as well as any other IC components (e.g., one or more of the non-planar transistors described herein). In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 11) or other logic that is configured to store information in the memory devices or execute instructions stored in the memory array.

FIG. 9 is a cross-sectional side view of an IC device 1600 that may include one or more vertical ESD diodes in accordance with any of the embodiments disclosed herein. The IC device 1600 may be formed on a substrate 1602 (e.g., the wafer 1500 of FIG. 8A) and may be included in a die (e.g., the die 1502 of FIG. 8B). The substrate 1602 may be any substrate as described herein. The substrate 1602 may be part of a singulated die (e.g., the dies 1502 of FIG. 8B) or a wafer (e.g., the wafer 1500 of FIG. 8A).

The IC device 1600 may include one or more device layers 1604 disposed on the substrate 1602. The device layer 1604 may include features of one or more transistors 1640 (e.g., metal-oxide-semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The IC device 1600 may include one or more vertical ESD diodes at any suitable location in the IC device 1600.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 9 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 9). Although a particular number of interconnect layers 1606-1610 is depicted in FIG. 9, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 9. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 9. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

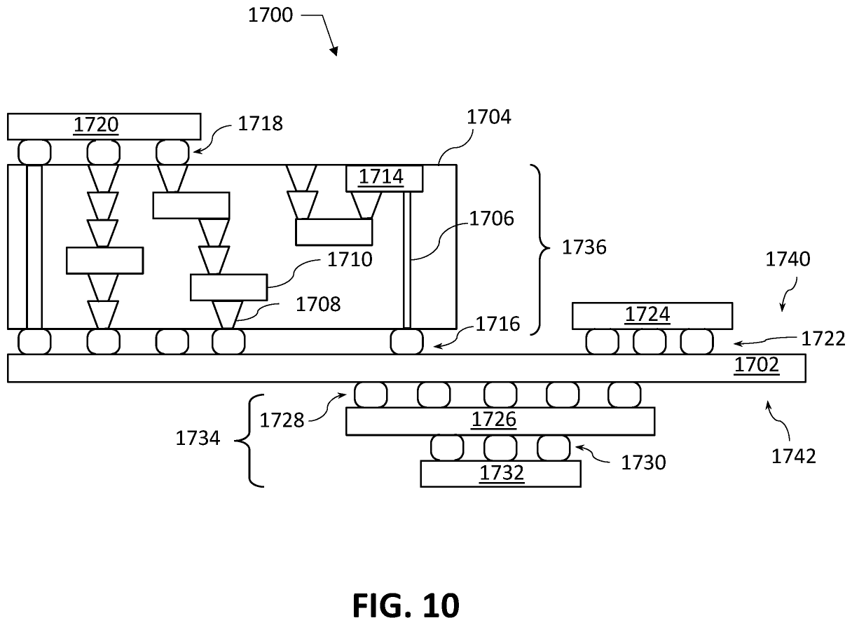

FIG. 10 is a cross-sectional side view of an IC device assembly 1700 that may include components having or being associated with (e.g., being electrically connected by means of) one or more vertical ESD diodes in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may include one or more of the non-planar transistors disclosed herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 10 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 10) male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 10, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 8B), an IC device (e.g., the IC device 1600 of FIG. 9), or any other suitable component. In some embodiments, the IC package 1720 may include one or more vertical ESD diodes, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 10, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 10 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 11 is a block diagram of an example computing device 1800 that may include one or more vertical ESD diodes in accordance with any of the embodiments disclosed herein. For example, any suitable ones of the components of the computing device 1800 may include a die (e.g., the die 1502 (FIG. 8B)) having one or more vertical ESD diodes. Any one or more of the components of the computing device 1800 may include, or be included in, an IC device 1600 (FIG. 9). Any one or more of the components of the computing device 1800 may include, or be included in, an IC device assembly 1700 (FIG. 10).

A number of components are illustrated in FIG. 11 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 11, but the computing device 1800 may include interface circuitry for coupling to the one or more components. For example, the computing device 1800 may not include a display device 1812, but may include display device interface circuitry (e.g., a connector and driver circuitry) to which a display device 1812 may be coupled. In another set of examples, the computing device 1800 may not include an audio input device 1816 or an audio output device 1814, but may include audio input or output device interface circuitry (e.g., connectors and supporting circuitry) to which an audio input device 1816 or audio output device 1814 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random-access memory (STT-MRAM).

In some embodiments, the computing device 1800 may include a communication chip 1806 (e.g., one or more communication chips). For example, the communication chip 1806 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1806 may implement any of a number of wireless standards or protocols, including but not limited to Institute for Electrical and Electronic Engineers (IEEE) standards including Wi-Fi (IEEE 1402.11 family), IEEE 1402.18 standards (e.g., IEEE 1402.18-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.18 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.18 standards. The communication chip 1806 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1806 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1806 may operate in accordance with other wireless protocols in other embodiments. The computing device 1800 may include an antenna 1808 to facilitate wireless communications and/or to receive other wireless communications (such as AM or FM radio transmissions).

In some embodiments, the communication chip 1806 may manage wired communications, such as electrical, optical, or any other suitable communication protocols (e.g., the Ethernet). As noted above, the communication chip 1806 may include multiple communication chips. For instance, a first communication chip 1806 may be dedicated to shorter-range wireless communications such as Wi-Fi or Bluetooth, and a second communication chip 1806 may be dedicated to longer-range wireless communications such as GPS, EDGE, GPRS, CDMA, WiMAX, LTE, EV-DO, or others. In some embodiments, a first communication chip 1806 may be dedicated to wireless communications, and a second communication chip 1806 may be dedicated to wired communications.

The computing device 1800 may include a battery/power circuitry 1810. The battery/power circuitry 1810 may include one or more energy storage devices (e.g., batteries or capacitors) and/or circuitry for coupling components of the computing device 1800 to an energy source separate from the computing device 1800 (e.g., AC line power).

The computing device 1800 may include a display device 1812 (or corresponding interface circuitry, as discussed above). The display device 1812 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1814 (or corresponding interface circuitry, as discussed above). The audio output device 1814 may include any device that generates an audible indicator, such as speakers, headsets, or earbuds, for example.

The computing device 1800 may include an audio input device 1816 (or corresponding interface circuitry, as discussed above). The audio input device 1816 may include any device that generates a signal representative of a sound, such as microphones, microphone arrays, or digital instruments (e.g., instruments having a musical instrument digital interface (MIDI) output).

The computing device 1800 may include another output device 1818 (or corresponding interface circuitry, as discussed above). Examples of the other output device 1818 may include an audio codec, a video codec, a printer, a wired or wireless transmitter for providing information to other devices, or an additional storage device.

The computing device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may include a global positioning system (GPS) device 1822 (or corresponding interface circuitry, as discussed above). The GPS device 1822 may be in communication with a satellite-based system and may receive a location of the computing device 1800, as known in the art.

The computing device 1800 may include a security interface device 1824. The security interface device 1824 may include any device that provides security features for the computing device 1800 or for any individual components therein (e.g., for the processing device 1802 or for the memory 1804). Examples of security features may include authorization, access to digital certificates, access to items in keychains, etc. Examples of the security interface device 1824 may include a software firewall, a hardware firewall, an antivirus, a content filtering device, or an intrusion detection device.

In some embodiments, the computing device 1800 may include a temperature detection device 1826 and a temperature regulation device 1828.

The temperature detection device 1826 may include any device capable of determining temperatures of the computing device 1800 or of any individual components therein (e.g., temperatures of the processing device 1802 or of the memory 1804). In various embodiments, the temperature detection device 1826 may be configured to determine temperatures of an object (e.g., the computing device 1800, components of the computing device 1800, devices coupled to the computing device, etc.), temperatures of an environment (e.g., a data center that includes, is controlled by, or otherwise associated with the computing device 1800), and so on. The temperature detection device 1826 may include one or more temperature sensors. Different temperature sensors of the temperature detection device 1826 may have different locations within and around the computing device 1800. A temperature sensor may generate data (e.g., digital data) representing detected temperatures and provide the data to another device, e.g., to the temperature regulation device 1828, the processing device 1802, the memory 1804, etc. In some embodiments, a temperature sensor of the temperature detection device 1826 may be turned on or off, e.g., by the processing device 1802 or an external system. The temperature sensor detects temperatures when it is on and does not detect temperatures when it is off. In other embodiments, a temperature sensor of the temperature detection device 1826 may detect temperatures continuously and automatically or detect temperatures at predefined times or at times triggered by an event associated with the computing device 1800 or any components therein.

The temperature regulation device 1828 may include any device configured to change (e.g., decrease) temperatures, e.g., based on one or more target temperatures and/or based on temperature measurements performed by the temperature detection device 1826. A target temperature may be a preferred temperature. A target temperature may depend on a setting in which the computing device 1800 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 1800 can be different. In some embodiments, cooling provided by the temperature regulation device 1828 may be a multi-stage process with temperatures ranging from room temperature to 4K or lower.

In some embodiments, the temperature regulation device 1828 may include one or more cooling devices. Different cooling devices may have different locations within and around the computing device 1800. A cooling device of the temperature regulation device 1828 may be associated with one or more temperature sensors of the temperature detection device 1826 and may be configured to operate based on temperatures detected by the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 1800 is satisfied. In response to determining that one or more temperature-related condition associated with the temperature of the computing device 1800 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 1828 may operate with various cooling mechanisms, such as evaporation cooling, radiation cooling, conduction cooling, convection cooling, other cooling mechanisms, or any combination thereof. A cooling device of the temperature regulation device 1828 may include a cooling agent, such as water, oil, liquid nitrogen, liquid helium, etc. In some embodiments, the temperature regulation device 1828 may be, for example, a dilution refrigerator, a helium-3 refrigerator, or a liquid helium refrigerator. In some embodiments, the temperature regulation device 1828 or any portions thereof (e.g., one or more of the individual cooling devices) may be connected to the computing device 1800 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 1800 (or components thereof) can be reduced, while the computing efficiency may be improved. For example, when the computing device 1800 (or components thereof) operates at lower temperatures, energy dissipation (e.g., heat dissipation) may be reduced. Further, energy consumed by semiconductor components (e.g., energy needed for switching transistors of any of the components of the computing device 1800) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 1800 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

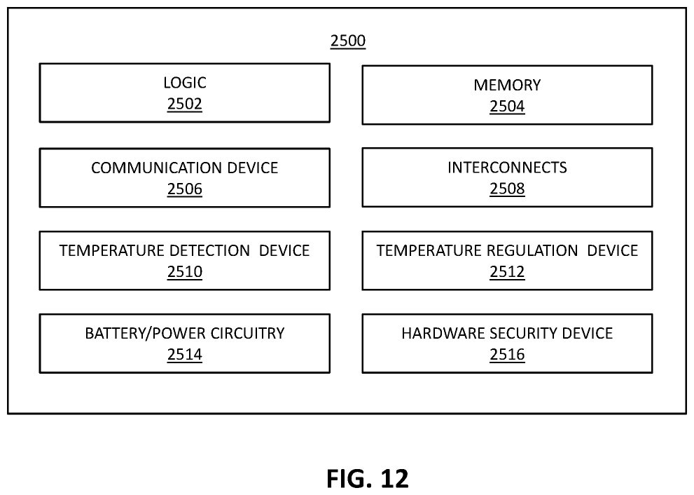

FIG. 12 is a block diagram of an example processing device 2500 that may include one or more IC devices with one or more vertical ESD diodes in accordance with any of the embodiments disclosed herein. For example, any suitable ones of the components of the processing device 2500 may include a die (e.g., the die 1502 of FIG. 8) having one or more vertical ESD diodes as described herein. Any one or more of the components of the processing device 2500 may include, or be included in, an IC device 1600 of FIG. 9 or an IC device assembly 1700 of FIG. 10. Any one or more of the components of the processing device 2500 may include, or be included in, a computing device 1800 of FIG. 11; for example, the processing device 2500 may be the processing device 1802 of the computing device 1800.

A number of components are illustrated in FIG. 12 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 12, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 1604 (FIG. 12). In some embodiments, the memory 2504 may be a designated device configured to provide storage functionality for the components of the processing device 2500 (i.e., local), while the memory 1604 may be configured to provide system-level storage functionality for the entire computing device 1600 (i.e., global). In some embodiments, the memory 2504 may include memory that shares a die with the logic circuitry 2502.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m₁, m₂, . . . , mₙ) in which each member mᵢ is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 1606 (FIG. 12). In some embodiments, the communication device 2506 may be a designated device configured to provide communication functionality for the components of the processing device 2500 (i.e., local), while the communication chip 1606 may be configured to provide system-level communication functionality for the entire computing device 1600 (i.e., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 2500 may include a temperature detection device 2510 which may be implemented substantially as described above with reference to the temperature detection device 1826 of FIG. 12 but configured to determine temperatures on a more local scale, i.e., of the processing device 2500 of components thereof. In some embodiments, the temperature detection device 2510 may be a designated device configured to provide temperature detection functionality for the components of the processing device 2500 (i.e., local), while the temperature detection device 1826 may be configured to provide system-level temperature detection functionality for the entire computing device 1800 (i.e., global).

The processing device 2500 may include a temperature regulation device 2512 which may be implemented substantially as described above with reference to the temperature regulation device 1828 of FIG. 11 but configured to regulate temperatures on a more local scale, i.e., of the processing device 2500 of components thereof. In some embodiments, the temperature regulation device 2512 may be a designated device configured to provide temperature regulation functionality for the components of the processing device 2500 (i.e., local), while the temperature regulation device 1828 may be configured to provide system-level temperature regulation functionality for the entire computing device 1800 (i.e., global).

The processing device 2500 may include a battery/power circuitry 2514 which may be implemented substantially as described above with reference to the battery/power circuitry 1810 of FIG. 11. In some embodiments, the battery/power circuitry 2514 may be a designated device configured to provide battery/power functionality for the components of the processing device 2500 (i.e., local), while the battery/power circuitry 1810 may be configured to provide system-level battery/power functionality for the entire computing device 1800 (i.e., global).

The processing device 2500 may include a hardware security device 2516 which may be implemented substantially as described above with reference to the security interface device 1824 of FIG. 11. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

### Select Examples

The following paragraphs provide various examples of the embodiments disclosed herein.

Example 1 provides a device including a device area extending in a first direction and a second direction; and a plurality of devices formed across the device area, where one of the devices includes a semiconductor region having a first end and a second end, the first end and the second end on opposite sides of the semiconductor region in a third direction, the third direction perpendicular to the first direction and the second direction; a first doped region coupled to the first end of the semiconductor region; and a second doped region coupled to the second end of the semiconductor region.

Example 2 provides the device of example 1, where the first doped region has a first carrier type, and the second doped region has a second carrier type, the first carrier type different from the second carrier type.

Example 3 provides the device of example 2, where the first doped region is a p-type region, and the second doped region is an n-type region.

Example 4 provides the device of any preceding example, where the first doped region has a first width, and the second doped region has a second width greater than the first width.

Example 5 provides the device of any preceding example, where semiconductor region includes a first portion and a second portion, the first portion having a first width in the first direction, and the second portion having a second width in the first direction, the second width greater than the first width.

Example 6 provides the device of example 5, where the first portion of the semiconductor region includes the first end of the semiconductor region, and the second portion of the semiconductor region includes the second end of the semiconductor region.

Example 7 provides the device of any preceding example, where the one of the devices is a two-terminal device.

Example 8 provides the device of example 7, further including a first metal region forming a first terminal is coupled to the first doped region, and a second metal region forming a second terminal is coupled to the second doped region.

Example 9 provides the device of any preceding example, where the device area further includes a plurality of transistors, and the first doped region is electrically coupled to at least one transistor in the device area.

Example 10 provides the device of example 9, where the second doped region is electrically coupled to an electrical ground.

Example 11 provides an IC device including a transistor region including a plurality of transistors, the transistor region along a device plane; a diode region along the device plane; and a diode in the diode region, the diode including a semiconductor region having a first end and a second end, the first end and the second end on opposite sides of the device plane; a first doped region coupled to the first end; and a second doped region coupled to the second end.

Example 12 provides the IC device of example 11, where the first doped region includes a p-type semiconductor, and the second doped region includes an n-type semiconductor.

Example 13 provides the IC device of example 11 or 12, where the first doped region has a first width, and the second doped region has a second width greater than the first width.

Example 14 provides the IC device of any of examples 11-13, where the transistor region includes a transistor having a source or drain (S/D) region, the S/D region and the first doped region within a second plane, the second plane over the device plane.

Example 15 provides the IC device of any of examples 11-14, further including a first metal region coupled to the first doped region and a second metal region coupled to the second doped region.

Example 16 provides the IC device of any of examples 11-15, where the first doped region is electrically coupled to at least one transistor in the transistor region.

Example 17 provides the IC device of example 16, where the second doped region is electrically coupled to an electrical ground.

Example 18 provides the IC device of any of examples 11-17, where the IC device is coupled to a circuit board.

Example 19 provides a device including a stack of horizontal structures, each structure in the stack having a first end and a second end; a vertical structure coupled to the first ends of the horizontal structures, the vertical structure having an upper end and a lower end; a first doped region coupled to the upper end of the vertical structure and an upper one of the stack of horizontal structures; and a second doped region coupled to the lower end of the vertical structure and a lower one of the stack of horizontal structures, the first doped region arranged over the second doped region.

Example 20 provides the device of example 19, where the first doped region has a first carrier type, and the second doped region has a second carrier type, the first carrier type different from the second carrier type.

Example 21 provides the device of example 19 or 20, where the vertical structure is a first vertical structure, the IC device including a second vertical structure coupled to the second ends of the horizontal structures, where the first doped region is coupled to an upper end of the second vertical structure and the second doped region is coupled to a lower end of the second vertical structure.

Example 22 provides a diode including a stack of horizontal structures, each structure in the stack having a first end and a second end; a first vertical semiconductor structure coupled to the first ends of the horizontal structures, the first vertical structure having a first upper end and a first lower end; a second vertical semiconductor structure coupled to the second ends of the horizontal structures, the second vertical structure having a second upper end and a second lower end; a first contact coupled to the first upper end of the first vertical semiconductor structure; and a second contact coupled to the second lower end of the second vertical semiconductor structure.

Example 23 provides the diode of example 22, where the first vertical semiconductor structure has a first carrier type, and the second vertical semiconductor structure has a second carrier type, the first carrier type different from the second carrier type.

Example 24 provides the diode of example 22 or 23, where the diode does not include a conductor around the stack of horizontal structures.

Example 25 provides the diode of any of examples 22-24, where the diode does not include a gate.

Example 26 provides the diode of any of examples 22-25, where the diode is a first diode of an IC device, the IC device further including a transistor.

Example 27 provides the diode of example 26, where a terminal of the transistor is coupled to one of the first contact and the second contact.

Example 28 provides the diode of example 26 or 27, where the transistor and the diode are in a device layer of the IC device.

Example 29 provides the diode of any of examples 26-28, where the IC device is coupled to a circuit board.

Example 30 provides the diode of any of examples 26-28, where the IC device is a component of a package.

Example 31 provides an IC package that includes an IC die, including one or more of the IC devices according to any one of the preceding examples. The IC package may also include a further component, coupled to the IC die.

Example 32 provides the IC package according to example 31, where the further component is one of a package substrate, a flexible substrate, or an interposer.

Example 33 provides the IC package according to examples 31 or 32, where the further component is coupled to the IC die via one or more first level interconnects.

Example 34 provides the IC package according to example 33, where the one or more first level interconnects include one or more solder bumps, solder posts, or bond wires.

Example 35 provides a computing device that includes a circuit board; and an IC die coupled to the circuit board, where the IC die includes one or more of the transistor/IC devices according to any one of the preceding examples (e.g., transistor/IC devices according to any one of examples 1-30), and/or the IC die is included in the IC package according to any one of the preceding examples (e.g., the IC package according to any one of examples 31-34).

Example 36 provides the computing device according to example 35, where the computing device is a wearable computing device (e.g., a smart watch) or hand-held computing device (e.g., a mobile phone).

Example 37 provides the computing device according to examples 35 or 36, where the computing device is a server processor.

Example 38 provides the computing device according to examples 35 or 36, where the computing device is a motherboard.

Example 39 provides the computing device according to any one of examples 35-38, where the computing device further includes one or more communication chips and an antenna.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

What is claimed is:

1. A device comprising:
a device area extending in a first direction and a second direction; and
a plurality of devices formed across the device area, wherein one of the devices comprises:
a semiconductor region having a first end and a second end, the first end and the second end on opposite sides of the semiconductor region in a third direction, the third direction perpendicular to the first direction and the second direction;
a first doped region coupled to the first end of the semiconductor region; and
a second doped region coupled to the second end of the semiconductor region.

2. The device of claim 1, wherein the first doped region has a first carrier type, and the second doped region has a second carrier type, the first carrier type different from the second carrier type.

3. The device of claim 2, wherein the first doped region is a p-type region, and the second doped region is an n-type region.

4. The device of claim 1, wherein the first doped region has a first width, and the second doped region has a second width greater than the first width.

5. The device of claim 1, wherein semiconductor region comprises a first portion and a second portion, the first portion having a first width in the first direction, and the second portion having a second width in the first direction, the second width greater than the first width.

6. The device of claim 5, wherein the first portion of the semiconductor region comprises the first end of the semiconductor region, and the second portion of the semiconductor region comprises the second end of the semiconductor region.

7. The device of claim 1, wherein the one of the devices is a two-terminal device.

8. The device of claim 7, further comprising a first metal region forming a first terminal is coupled to the first doped region, and a second metal region forming a second terminal is coupled to the second doped region.

9. The device of claim 1, wherein the device area further comprises a plurality of transistors, and the first doped region is electrically coupled to at least one transistor in the device area.

10. The device of claim 9, wherein the second doped region is electrically coupled to an electrical ground.

11. An integrated circuit (IC) device comprising:
a transistor region comprising a plurality of transistors, the transistor region along a device plane;
a diode region along the device plane; and
a diode in the diode region, the diode comprising:
a semiconductor region having a first end and a second end, the first end and the second end on opposite sides of the device plane;
a first doped region coupled to the first end; and
a second doped region coupled to the second end.

12. The IC device of claim 11, wherein the first doped region comprises a p-type semiconductor, and the second doped region comprises an n-type semiconductor.

13. The IC device of claim 11, wherein the first doped region has a first width, and the second doped region has a second width greater than the first width.

14. The IC device of claim 11, wherein the transistor region comprises a transistor having a source or drain (S/D) region, the S/D region and the first doped region within a second plane, the second plane over the device plane.

15. The IC device of claim 11, further comprising a first metal region coupled to the first doped region and a second metal region coupled to the second doped region.

16. The IC device of claim 11, wherein the first doped region is electrically coupled to at least one transistor in the transistor region.

17. The IC device of claim 16, wherein the second doped region is electrically coupled to an electrical ground.

18. The IC device of claim 11, wherein the IC device is coupled to a circuit board.

19. A device comprising:
a stack of horizontal structures, each structure in the stack having a first end and a second end;
a vertical structure coupled to the first ends of the horizontal structures, the vertical structure having an upper end and a lower end;
a first doped region coupled to the upper end of the vertical structure and an upper one of the stack of horizontal structures; and
a second doped region coupled to the lower end of the vertical structure and a lower one of the stack of horizontal structures, the first doped region arranged over the second doped region.

20. The device of claim 19, wherein the first doped region has a first carrier type, and the second doped region has a second carrier type, the first carrier type different from the second carrier type.
